(19) United States
(12) Patent Application Publication
(10) Pub. No.: US 2005/0067681 A1
(43) Pub. Date: Mar. 31, 2005

(54) Package having integral lens and wafer-scale fabrication method therefor

(75) Inventors: Catherine De Villeneuve, San Jose, CA (US); Giles Humpston, San Jose, CA (US); David B. Tuckerman, Orinda, CA (US)

Correspondence Address: LERNER DAVID, LITENBERG, KRUMHOLZ & MENTLIK, 600 SOUTH AVENUE WEST, WESTFIELD, NJ, 07090, US

(73) Assignee: Tessera, Inc., San Jose, CA (US)

(21) Appl. No.: 10/928,839

(22) Filed: Aug. 27, 2004

Related U.S. Application Data
(60) Provisional application No. 60/568,041, filed on May 4, 2004.
(60) Provisional application No. 60/532,341, filed on Dec. 23, 2003.
(60) Provisional application No. 60/515,615, filed on Oct. 29, 2003.
(60) Provisional application No. 60/506,500, filed on Sep. 26, 2003.

(51) Int. Cl. H01L 31/0203

(52) U.S. Cl. 257/678

(57) ABSTRACT

A covered chip having an optical element integrated in the cover is provided which includes a chip having a front surface, an optically active circuit area, and bond pads disposed at the front surface. The chip is covered by an at least partially optically translucent or transparent unitary cover that is mounted to the front surface of the chip, and has at least one optical element integrated in the unitary cover. The cover is further aligned with the optically active circuit area and vertically spaced from the optically active circuit area.

### CROSS-REFERENCE TO RELATED APPLICATIONS

This application claims the benefit of U.S. Provisional Application No. 60/568,041 filed on May 4, 2004, entitled “Structure And Method Of Making Capped Chips”; U.S. Provisional Application No. 60/506,500 filed on Sep. 26, 2003 entitled “Wafer-scale Hermetic Package”; U.S. Provisional Application No. 60/515,615 entitled “Wafer-scale Hermetic Package, Wiring Trace Under Bump Metallization, and Solder Sphere Mask” filed on Oct. 29, 2003; and U.S. Provisional Application No. 60/532,341 entitled “Wafer-Scale Hermetic Package, Wiring Trace Under Bump Metallization, and Solder Sphere Mask” filed on Dec. 23, 2003, for all of which the disclosures are hereby incorporated by reference herein.

### BACKGROUND OF THE INVENTION

The present invention relates to the packaging of optically active elements, especially micro-structure elements, such as photo-sensitive chips and optical source chips.

Increases in the circuit density of microelectronics now routinely permit optical devices such as photo-sensitive devices, e.g., imaging devices, and optical sources to be implemented at the scale of an integrated circuit or “chip”. Such advances, together with improved performance and lowered cost, now permit microelectronic image sensors to be used in a variety of applications such as digital photography, surveillance, certain cellular telephones, video conferencing equipment, e.g., video telephones, automotive driver aids, toys, and for control of machinery, to name a few examples.

Such optical devices require packaging in microelectronic elements that either have an opening for a lens, or are otherwise transparent to optical radiation at a wavelength of interest.

Optical imaging devices are frequently implemented using complementary metal oxide semiconductor (CMOS) devices formed in respective chips of a silicon wafer. The active component of a CMOS solid state imaging device is an array of photon detectors disposed in an optically active area of a chip, the array of detectors typically being coupled directly to image processing electronics. Because the area of each chip typically has a size of only a few millimeters on each side, typically many such imaging sensor chips are formed on a single wafer at the same time.

Image sensors pose a special concern for their packaging. Due to the small size of the photon detectors that are found in such image sensors, it is important for image sensors to be protected against the possibility of contamination, e.g., due to dust, which would ordinarily render the image sensor useless. Hence, it is desirable to package image sensors soon after they are made, and to do so while the chips which contain them are still in wafer form.

Most image sensors also require some sort of optically active element, e.g., a lens, filter, etc., to be placed in the path of light above the image sensor to help in focusing light onto the sensor, for example. Typically, an optically active element typically is mounted onto a circuit board as a “lens “turret” over a package which contains the image sensor, or a lens turret is mounted to a separately packaged image sensor. In another type of package, a lens structure is mounted to the top surface of the chip, such that the bond pads of the chip are exposed and bonded to contacts of the package.

In still another type of structure shown in one embodiment of U.S. Pat. No. 6,583,444 B2 (“the '444 patent), a transparent or translucent encapsulant covers a surface of a chip containing an optoelectronic element. In the exemplary manufacturing method shown in the '444 patent, a wafer containing photo-sensitive chips are first severed into individual chips before an encapsulant is flowed over the optoelectronic surface of the chip and a lid including an optical element is formed on the chips.

Some other types of chips include sensitive components which must be kept covered in order for the chips to operate properly. Filters having “surface acoustic wave” (SAW) devices are an example of such chips.

Miniature SAW devices can be made in the form of a wafer formed from or incorporating an acoustically active material such as lithium niobate material. The wafer is treated to form a large number of SAW devices, and typically also is provided with electrically conductive contacts used to make electrical connections between the SAW device and other circuit elements. After such treatment, the wafer is severed to provide individual devices. SAW devices fabricated in wafer form have been provided with caps while still in wafer form, prior to severing. For example, as disclosed in U.S. Pat. No. 6,429,511 a cover wafer formed from a material such as silicon can be treated to form a large number of hollow projections and then bonded to the top surface of the active material wafer, with the hollow projections facing toward the active wafer. After bonding, the cover wafer is polished to remove the material of the cover wafer down to the projections. This leaves the projections in place as caps on the active material wafer, and thus forms a composite wafer with the active region of each SAW device covered by a cap.

Such a composite wafer can be severed to form individual units. The units obtained by severing such a wafer can be mounted on a substrate such as a chip carrier or circuit panel and electrically connected to conductors on the substrate by wire-bonding to the contacts on the active wafer after mounting, but this requires that the caps have holes of a size sufficient to accommodate the wire bonding process. This increases the area of active wafer required to form each unit, requires additional operations and results in an assembly considerably larger than the unit itself.

In another alternative disclosed by the '511 patent, terminals can be formed on the top surfaces of the caps and electrically connected to the contacts on the active wafer prior to severance as, for example, by metallic vias formed in the cover wafer prior to assembly. However, formation of terminals on the caps and vias for connecting the terminals to the contacts on the active wafer requires a relatively complex series of steps. Moreover, the '511 patent does not teach structures or methods which permit lenses or other optically active elements to be incorporated into the caps.

### SUMMARY OF THE INVENTION

According to an aspect of the invention, a covered chip having an optical element integrated in the cover, includes a chip having a front surface, an optically active circuit area and bond pads disposed at the front surface. The chip is covered by an at least partially optically translucent or transparent unitary cover that is mounted to the front surface of the chip, having at least one optical element integrated in the unitary cover, the cover being aligned with the optically active circuit area and vertically spaced from the optically active circuit area.

According to another aspect of the invention, a covered chip is provided which includes a chip having a front surface, an optically active circuit area at the front surface and bond pads disposed on the front surface. A unitary cover is mounted to the front surface of the chip, the unitary cover consisting essentially of one or more polymers, having an inner surface adjacent to the chip and an outer surface opposite the inner surface. The unitary cover includes one or more mounts disposed at positions above the outer surface, the mounts adapted for mounting an optical element.

According to further preferred aspects of the invention, one or more optical elements are mounted to the mounts of the unitary cover.

According to yet another aspect of the invention, a method is provided for simultaneously forming a plurality of covered optically active chips. According to such method, an array of optically active chips is provided, each chip having a front surface and an optically active circuit area at the front surface. An array of unitary optically transmissive covers is provided, each cover having at least one of (i) an integrated optical element and (ii) a mount adapted to hold an optical element. At least ones of the chips are aligned to ones of the covers, and at least some of the aligned ones of the chips are simultaneously joined to at least some of the covers to form the covered chips.

### DETAILED DESCRIPTION

Microelectronic elements such as semiconductor chips or “dies” commonly are provided in packages which protect the die or other element from physical damage, and which facilitate mounting of the die on a circuit panel or other element.

One type of microelectronic package includes a cap, which encloses a cavity overlying an active area of the packaged chip. For example, commonly owned U.S. Provisional Application No. 60/449,673 filed Feb. 25, 2003 and commonly owned, co-pending U.S. patent application Ser. No. 10/786,825 filed Feb. 25, 2004, the disclosures of which are hereby incorporated by reference herein, describe ways of mounting caps to chips, especially at a wafer scale, to permit the making of interconnects to the front surfaces of the chips from outside an area in which an active device area of the chip is located.

The embodiments of the invention address a particular need to provide a method of packaging chips having optoelectronic devices such as imaging devices. Such chips are typically packaged in assemblies with one or more lenses, e.g., lens turrets. In packaging such chips it is important to avoid the surface of the optoelectronic device from becoming contaminated by a particle, e.g., from dust. In addition, it is desirable to provide an efficient and reliable way of packaging optoelectronic chips together with optical elements such as lenses and/or lens mounts, despite a difference in the coefficient of thermal expansion (CTE) between the chip and the optical element.

FIG. 1 illustrates a covered chip 10 according to an embodiment of the invention, which includes an optoelectronic chip 11 to which a unitary cover 12 is mounted that has an optical element integrated therewith. As used herein, the term “optical element” is intended to cover all manner of passive elements having an optical function, including, but not limited to elements having an effect of focusing, scattering, collimating, reflecting, refracting, diffracting, absorbing, filtering, fluorescing, etc., on wavelengths of interest, regardless of whether such wavelengths are visible or not visible to the human eye. Stated another way, an optical element is more than merely a transmission medium disposed at a normal angle to the chip 11, when the unitary cover is mounted to the chip in final position relative to the chip. Thus, in one example, the optical element has an effect of altering one or more of the characteristics of the light, such as by focusing or collimating the light. Examples of optical elements include lenses, diffraction gratings, holograms, a reflector (which may be partly transmissive and partly reflective), a refracting element, e.g., a prism having at least one face disposed at a non-normal angle to the light, and a filter. A variety of lenses of many different shapes, functions and features can be formed integrally with the unitary cover 12. For example, in one embodiment, a convex lens is formed integrally with the cover 12. In another embodiment, a concave lens is formed integrally with the cover 12. Moreover, such lens can be spherical or aspherical, as needed for a particular application. In a particular embodiment, a lens is provided which corrects for astigmatism in other optics or corrects for astigmatism in the optoelectronic device with which the covered chip is used.

As shown in FIG. 1, the optical element 14 is disposed in alignment above an optically active circuit area including an optoelectronic device 16 at a front surface 18 of the chip. Illustratively, in a particular embodiment, the optical element 14 is a lens, the lens used to focus light onto to the optoelectronic device 16. In such embodiment, the unitary cover 14 is provided as an element that is at least partially transparent or translucent wavelengths of interest. As shown, the unitary cover is provided as a molded element consisting essentially of a polymeric material in which the lens element forms an integral part of the unitary cover. In a particular embodiment, the lens element is molded simultaneously and integrally with the unitary cover, as by injection molding. Examples of polymeric materials used in fabricating optics, and which are suitable for fabricating the unitary cover include: polymethyl-methacrylate, polystyrene, polycarbonate, alkyl diglycol carbonate, polystyrene-co-acrylonitrile, polystyrene-co-methacrylate, poly-4-methyl-1-pentene, cyclic olefin copolymer, amorphous polyolefin, amorphous nylon, polyethersulfone, and polyetherimid.

One particular class of transparent and translucent materials, amorphous nylon, has a CTE of about 9 ppm/° K, which is somewhat greater than the CTE of silicon, but which is still less than one order of magnitude greater than silicon. Accordingly, with respect to embodiments described herein in which arrays of attached unitary covers are bonded to arrays of attached chips, e.g., in wafer form, the unitary covers can be fabricated from a material, such as amorphous nylon, which has a desirably low CTE. Another class of materials which can be used includes liquid crystal polymers. Certain liquid crystal polymers have CTE's less than one order of magnitude greater than the CTE of silicon, and in some cases as low as about 5 ppm/° K., and thus provide a good expansion match to silicon. The optical transmission per unit thickness of the liquid crystal polymers generally is lower than that of other transparent polymers, but nonetheless acceptable in many applications.

As further shown in FIG. 1, the bond pads 20 are disposed on the front surface of the chip 11. Conductive interconnections to the chip 11 are provided in through holes 22 disposed in the unitary cover 12. Such conductive interconnections can be provided in several different ways, as will be described further below. As particularly shown in FIG. 1, the conductive interconnections are made by a conductive bonding material that extends from the bond pads 20 of the chip 11 at least partially into the through holes disposed in the unitary cover 12. In one embodiment, the through holes are provided with solder-wettable metallizations 32, and the bonding material includes solder or other low-melting point or eutectic bonding material that adheres best when a solder-wettable surface is provided. As also shown in FIG. 1, the unitary cover 14 is spaced from the front surface 18 of the chip 11 by spacers 26. In a particular embodiment such as that shown in FIG. 1, the spacers 26 include cylindrical or spherical dielectric elements, such as those commonly available. The spacers are provided within a sealing medium 28 that is disposed next to peripheral edges 30 and other peripheral edges (not visible in the sectional view shown in FIG. 1) of the chip 11 as a “picture frame” ring seal for the covered chip 10.

Typically, the sealant used to form the ring seal 28 includes a material which has a low modulus of elasticity in order to maintain the optical element 14 in proper alignment and at a desired spacing relative to the optoelectronic element 16. However, the sealant material need not have high hermeticity, since the primary purpose of the cover and the seal is for preventing particle of the optoelectronic device, e.g., dust and droplet contamination, such as from condensation. Thus, for optoelectronic devices, the sealant 28 need not provide a hermetic seal according to the stringent standards normally associated with the packaging of SAW chips.

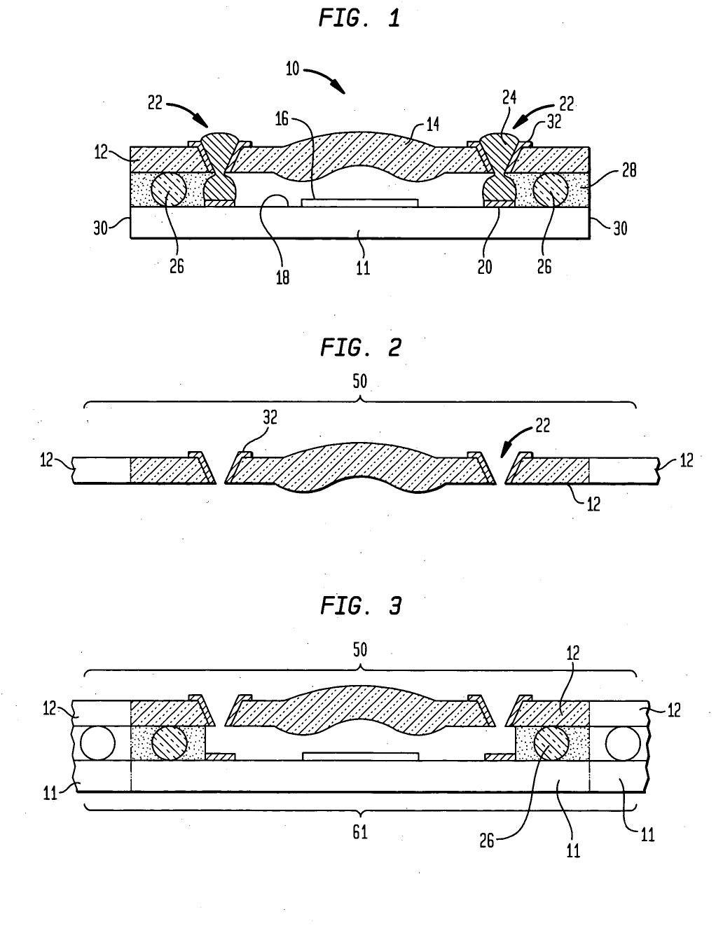

FIGS. 2-5 illustrate stages in a method of fabricating a covered chip according to an embodiment of the invention. FIG. 2 illustrates a unitary cover 12, to which two other unitary covers 12 having the same construction are attached, illustratively as a unitary element 50 including an array of unitary covers 12. In one embodiment, the unitary element 50 is a polymeric element, molded, as by a well-known molding process, e.g., injection molding, for making high density molded products. The through holes 22 of the unitary cover are desirably provided by the molding process, although alternatively, the through holes can be provided after the molding process by patterned etching, e.g., using lithographically patterned photoresist features. Alternatively, optical or mechanical methods, e.g., laser drilling, can be used to form the through holes. As further shown in FIG. 2, the through holes 22 have solder-wettable metallizations 32, such as can be provided, for example, through masked electroless plating onto the polymeric unitary cover, followed by electroplating.

FIG. 3 illustrates a subsequent stage in fabrication. AS shown therein, the unitary element 50, including an array of unitary covers 12, is mounted to a corresponding array 61 of chips 11, with the picture frame ring seal medium 28 and the spacers 26 disposed between chips 11 and the unitary element 50. At this stage of fabrication, the array 61 of chips 11 desirably remain attached, in form of a wafer or portion thereof, such that the unitary element 50 is mated to the attached chips. In one embodiment, the chips 11 remain attached on a wafer, and the unitary element 50 includes an array of covers, but which extends over smaller dimensions than the wafer. In such “tiled” approach, the ring seal medium is provided on each of the chips of a particular portion of the array of the chips. A particular unitary element 50 is then bonded to an array of chips on the wafer through the ring seal medium. Then, the alignment and bonding equipment is moved to another location of the wafer, and another particular unitary element 50 is bonded to another array of chips of the wafer. The process is then repeated multiple times until all of the chips of the wafer have been covered.

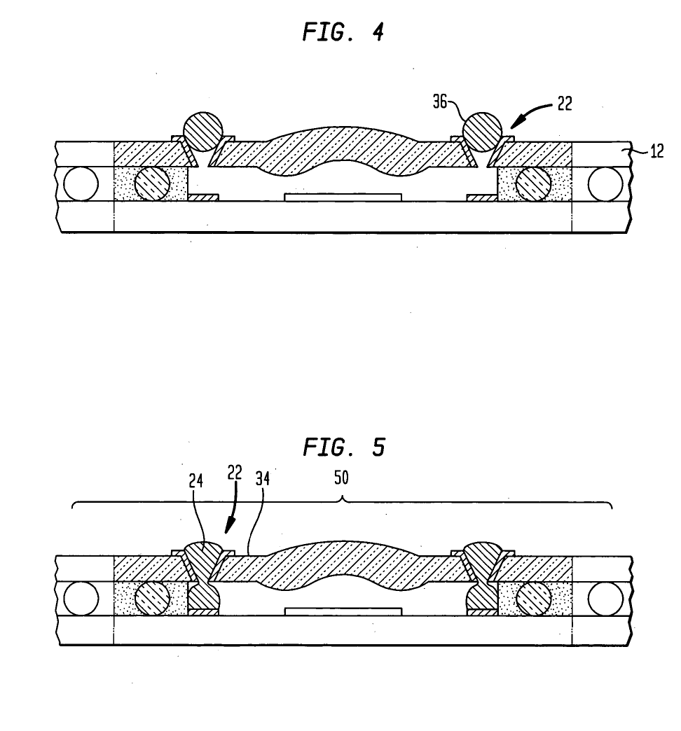

As further shown in FIG. 4, in such “tiled” process embodiment, solder balls 36 are aligned and placed in the metallized through holes 32 or at least placed on lands adjacent the metallized through holes. Thereafter, as shown in FIG. 5, the assembly including the wafer, with the plurality of tiled unitary elements 50 attached, is heated to a temperature sufficient to reflow the solder balls. This results in the solder material flowing down the metallizations 32 on the walls of the through holes 22 and bonding with the bond pads 20 of the chip 11. In such way, conductive interconnections are formed extending from the bond pads 20 up through the through holes 22 to the top surface 34 of the unitary cover 12.

After all of the unitary elements 50 are bonded to the chips of the wafer and the conductive interconnections are so formed, the chips are then severed into individual chips as shown in FIG. 1, each chip having its own conductive interconnections. With the optoelectronic element now being covered, the chip can now be integrated into a higher level package or assembly, at which time it can be handled according to less restrictive procedures than those used to fabricate the chip and to provide the covered chip.

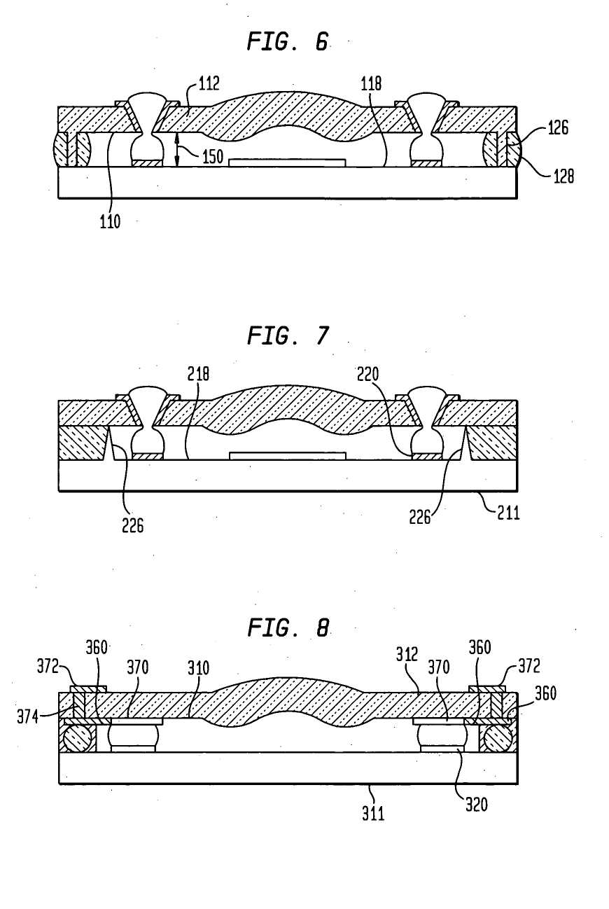

FIG. 6 illustrates a covered chip according to an alternative embodiment of the invention. In this embodiment, spacers 126 are integrated into the unitary cover 112, as integral molded parts of the unitary cover. In the embodiment shown in FIG. 6, the spacers are provided in form of posts or ribs which extend vertically downward from a bottom surface 110 of the unitary cover 112 to space the bottom surface 110 of the unitary cover 112 a predetermined distance from the front surface 118 of the chip. As particularly shown in FIG. 6, the spacers are provided in the region in which the picture frame ring-seal medium 128 is disposed.

In another embodiment shown in FIG. 7, spacers 226 are provided as elements extending upwardly from the front surface 218 of the chip 211. Such spacers are provided, for example, by the building up of one or more patterned material layers, e.g. through electroless and/or electroplating that are performed, for example, during back-end-of-the-line (BEOL) processing which is performed after the bond pads 220 are formed.

FIG. 8 illustrates another embodiment of the invention in which conductive interconnects are formed through the unitary cover 312, but which are offset from the bond pads 320 of the chip 311. In such embodiment, conductive traces 360 are provided at the bottom surface 310 of the unitary cover, the traces 360 being connected to lower contacts 370 that are disposed at positions corresponding to the bond pads 320 of the chip 311. The traces 360, in turn, are conductively connected to upper contacts 372 by a conductive member 374 which extends through the unitary cover 312. Illustratively, the conductive members are provided as plated through holes, and the traces 360, the lower contacts 370 and the upper contacts 372 are formed by plating, for example.

To form the covered chip shown in FIG. 8, the bond pads 320 are bonded to the lower contacts 370, as by solder bumps or conductive adhesive that are applied to the bond pads 320 or applied to the contacts 370. Thereafter, the unitary cover 312 is aligned to the chip 311 and bonded. As in the embodiment described above with reference to FIGS. 2-5, the application of solder bumps or adhesive to the chip 311 or the cover 312, and the aligning and bonding steps can be performed simultaneously for multiple chips and covers, while the chips remain attached to each other, such as in form of a wafer, and while multiple covers remain attached to each other. A self-curing adhesive, or alternatively, an ultraviolet light curable conductive adhesive can be utilized to simultaneously bond a large cover, e.g., cover of the entire wafer size, to chips of an entire wafer, to produce the structure shown in FIG. 8.

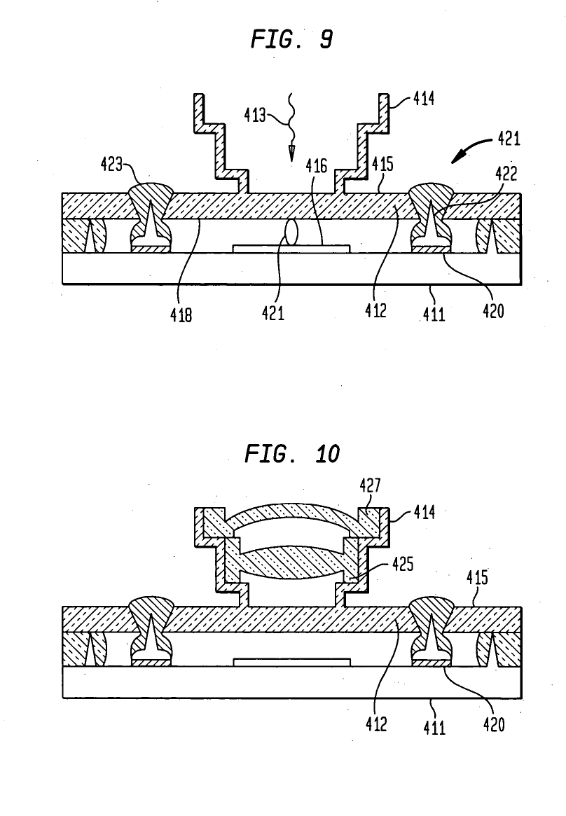

FIG. 9 is a sectional view illustrating another embodiment of the invention in which the unitary cover 412 has a mount 414 formed integrally with the unitary cover for the purpose of mounting an optical element. The mount 414 is disposed at a top surface 415 of the unitary cover 412, at a position overlying an optoelectronic element 416 of the chip 411. The mount preferably has a radially symmetric design, or is at least generally radially symmetric. In the particular embodiment shown in FIG. 9, the unitary cover 412 is an essentially transmissive element, being transparent to wavelengths of interest and having a top surface 415 and a bottom surface 418, both of which present essentially planar surfaces to the light 421, 423 which impinges onto the unitary cover, such that the characteristics of the light, e.g., the direction of the light, or beam characteristics, etc., are not significantly altered by the passage of the light through the unitary cover 414 to or from the optoelectronic element 416.

As further shown in FIG. 9, tapered stud bumps 422 are provided on the bond pads 420 of the chip 411. This type of interconnect is such as described in commonly assigned U.S. Provisional Application No. 60/568,041 filed May 4, 2004, which is incorporated by reference herein. The tapered stud bumps 422 provide a conductive element which extends at least partially through the through holes 421 of the unitary cover. Solder, conductive adhesive or other conductive material 423 disposed in contact with the tapered stud bumps 422 assists in providing a conductive interconnect extending from the bond pads 420 to the top surface 415 of the unitary cover 412. Where the conductive material 423 is a conductive organic material or other material which will wet the walls of through holes 421 without metallization of the walls, the step of metallizing the walls of the through holes discussed above with reference to FIG. 1 can be omitted.

FIG. 10 is a diagram further illustrating the embodiment shown in FIG. 9, after optical elements 425 and 427 have been mounted to the mounts 414 above the top surface 415 of the unitary cover. In the particular manner illustrated in FIG. 10, the optical elements include lenses. However, the optical elements can include any of other foregoing described types of optics, e.g., filters, diffraction gratings, holograms, etc., instead of or in addition to lenses. Optical elements 425, 427 are mounted to the mounts and permanently adhered thereto by any of several well-known methods such as those which involve localized heating including spin-welding, or ultra-sonic welding, or by a directed source of light, e.g., ultraviolet light or a laser. When the optical elements 425, 427 are mounted to the mounts 414 of the cover 412, since the optoelectronic element 416 of the chip 411 is protected from contamination by the cover 412, this step in fabrication can be performed under conditions which are less restrictive than those in which the cover 412 is mounted to the chip 411. Thus, the level of particles, e.g., dust, that are permitted to be present in the ambient when the optical elements 425, 427 are mounted to the cover 412 can be much greater than the maximum particle level that is permitted when the unitary cover 412 is first mounted to the chip. As an example, when the optoelectronic element is an imaging device, such as a charge-coupled device (CCD) array such as used in digital photography, a small particle which lands upon an imaging area of such CCD array will block an imaging area of the CCD array, causing the image captured by the CCD array to appear blotted out. Under such condition, the CCD array chip must be scrapped as defective. On the other hand, if the same size particle lands upon the top surface 415 of the cover 412 or on one of the optical elements 425, or 427, the chip is not rendered defective. The effect of the particle on the image is slight, because the particle landed upon one of the optical elements or the cover is not disposed in the focal plane of the image, and for that reason, does not block an area of the captured image.

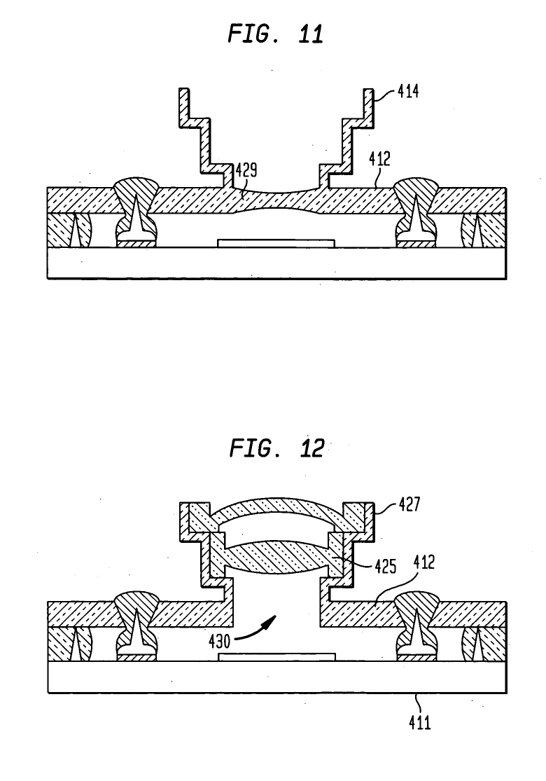

FIG. 11 illustrates another embodiment in which the unitary cover includes mounts 414 and an optical element 429, shown here as a concave lens, formed integrally with the unitary cover 412. A variety of optical elements including lenses of many different shapes, functions and features can be formed integrally with the unitary cover 412, as described above with reference to FIG. 1. For example, instead of a concave lens, a convex lens could be formed integrally with the cover 412. Alternatively, a spherical lens or an aspherical lens is formed integrally with the cover.

FIG. 12 illustrates yet another embodiment in which an opening 430 is disposed in the unitary cover 412 below the mounts 414 to which optical elements 425 and 427 are mounted. In this embodiment, the optical elements 425, 427 are mounted to the mounts 414 preferably before the cover 412 is mounted to the chip 411, in order to mitigate the above-described concern for particle contamination.

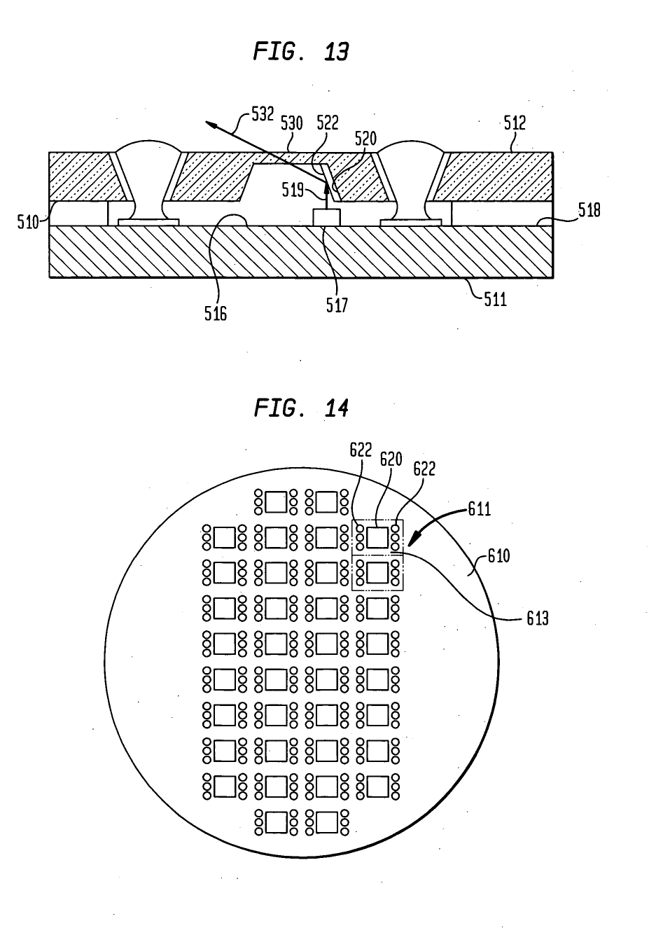

FIG. 13 is a sectional diagram illustrating yet another embodiment which is similar in all respects to the embodiment described above with respect to FIG. 1, except for the material and construction of the unitary cover 512 and the particular optoelectronic device provided on the chip 511. In this embodiment, the unitary cover 512 is fabricated of silicon or other material which has a CTE that closely matches the CTE of the chip 511 to which it is mounted, which itself may be fabricated in silicon or other semiconductor having a similar CTE. Although silicon is opaque to light at visible wavelengths, silicon is at least partially transparent or translucent at infrared wavelengths, such that a cover 512 made of silicon will at least pass infrared wavelengths, while blocking visible wavelengths. As further shown in FIG. 13, the cover has a thinned region 530 which is disposed above a device area 516 including a laser 517. In a particular embodiment, a reflector 522, being at least partially reflective, is provided on a sidewall 520 of the cover, between the bottom surface 510 and the thinned region 530. The reflector 522 can be provided by forming a metal coating on the sidewall, such as formed by electroplating. The laser 517 is disposed on the chip 511 so as to provide output in a direction 519 vertical to the major surface 518 of the chip 511 towards the reflector 522. As a result of the reflector 522, the beam output by the laser is reflected in a direction 532 through the thinned region of the cover 512 which is determined by the placement of the laser 517 in relation to the reflector 522 and the angle at which the reflector 522 makes to the beam output by the laser 517.

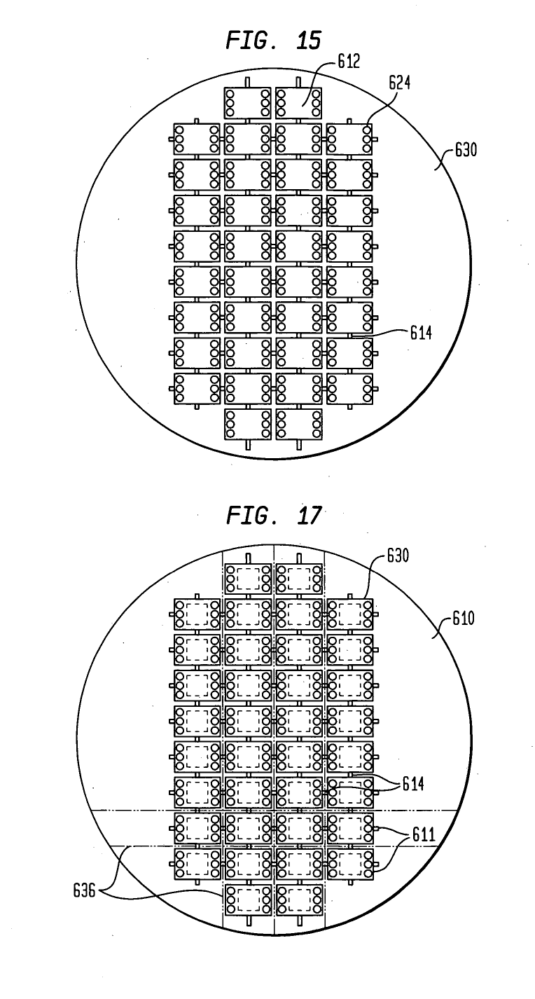

FIGS. 14-18 illustrate particular process embodiments of the invention which involve the simultaneous mounting of multiple covers to multiple chips, for example, chips which are attached in wafer form during such mounting process. For this reason, the embodiments shown in FIGS. 14-18 can be referred to as a “wafer-scale” packaging process. This embodiment is based upon a recognition that the CTE of certain polymeric materials is much greater than that of silicon and other semiconductors, and that thermal expansion of such materials is frequently non-isometric, such that the assembly process, when performed at elevated temperature, must specifically provide for differential and non-isometric thermal expansion of the material of the unitary covers relative to the chips to which they are being mounted.

FIG. 14 is a plan view illustrating a plurality of chips 611 which remain attached on a wafer as fabricated thereon. Each chip 611 includes a device area 620, including one or more optoelectronic elements, and a plurality of bond pads 622. The boundaries between the chips 611 are dicing channels 613, where the attached chips 611 will be severed later to provide individually packaged chips.

FIG. 15 is a plan view illustrating a unitary cover element 630 on which a plurality of unitary covers 612 are provided for forming a covered chip according to any of the embodiments described above relative to FIGS. 1-13. The unitary cover element 630 is provided for simultaneous mounting to a plurality of chips, e.g., all of the chips of a wafer. In the embodiment shown, the unitary cover element 630 is preferably fabricated as a single piece of molded polymeric material, and is fabricated, for example, by injection molding. Each unitary cover 612 is sized to fully contain the device area of the chip and includes an optical element formed integrally to the cover, such as the optical elements described above with reference to FIG. 1 and/or a mount used to mount an optical element, such as the mounts described above relative to FIGS. 9-12. Each cover 612 further includes one or more through holes 624 or conductive members extending from a bottom surface of the cover 612 to a top surface thereof, such as described above with reference to FIGS. 1-13.

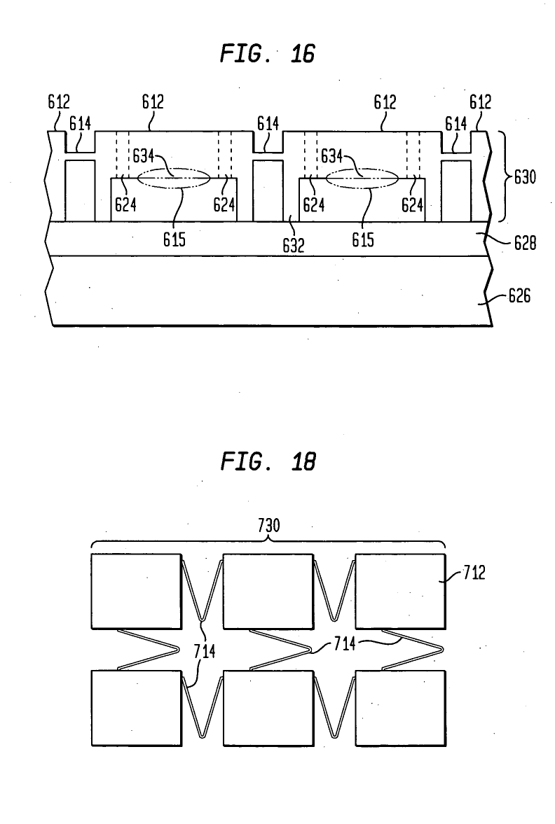

As further shown in FIG. 15, and as best shown in the partial sectional view of FIG. 16, at this stage of manufacture, individual covers 612 of the unitary cover element 630 are attached to each other through stress-bearing members 614, which desirably have much thinner cross-sectional area than the unitary covers 612, and accordingly are able to stretch, compress, bend, flex, or twist, as necessary when the individual unitary covers 612 of the cover element 630 is aligned and bonded to the chips of the wafer.

In addition, FIG. 15 illustrates a partial section of the unitary cover element 630, as temporarily supported during the mounting process on a supporting element 626 which is CTE-matched to the device wafer 610. Examples of such supporting element 626 include a platen formed of silicon or of a material that is CTE-matched to silicon, e.g., molybdenum, or any of several other known materials having a CTE matched to silicon.

As shown in FIG. 16, the top surface 615 of the unitary cover element 630 is disposed face down onto a temporary layer 628, to which edge members or posts 632 of each unitary cover 612 temporarily adhere. Such temporary layer 628 can be provided by an adhesive that is releasable upon applying a certain condition. For example, the temporary layer 628 can be provided as an adhesive that is released upon illumination of ultraviolet light. As further illustrated in FIG. 15, each unitary cover 612 includes an optical element 634 and through holes 624.

FIG. 17 illustrates a subsequent stage of fabrication in which the unitary cover element 630 has been aligned to the device wafer and the unitary covers 612 bonded to the individual chips of the device wafer 610, such as through the picture frame ring seal medium, as described above. At this time, the conductive interconnects are preferably formed through the covers 612 to the bond pads of the individual chips, through one or more of the techniques described above. Some techniques of forming the interconnects, e.g., application of solder balls and reflowing, described above relative to FIGS. 2-5, require performance at elevated temperature. In such case, the stress-bearing members connecting the individual covers deform as needed to bear the stress causing by differential thermal expansion between the unitary cover element 630 and the device wafer 610. Upon completion of the bonding process and formation of conductive interconnects through the covers 612, the chips 611 are then severed into individually covered chips by dicing along dicing channels 636.

As further illustrated in the plan view provided in FIG. 18, a portion of an alternative unitary cover element 730 is illustrated in which each unitary cover 712 is attached to other unitary covers by stress-bearing members 714 that are formed as spring-like elements which are easily bent, flexed, deformed, etc., to take up the stresses caused during the mounting process of the covers to the chips in wafer form and/or the process for forming conductive interconnects as described above.

The processes described above for mounting the covers to the chips and for providing conductive interconnects need not be performed to simultaneously mount all of the covers to all of the chips of an entire wafer. Instead, in an alternative process, only a plurality of the chips of a wafer, in form of an array, are mounted simultaneously to a corresponding number of covers. Thereafter, the process can be repeated to mount the covers to the chips of a different portion of the wafer, and the process then repeated again and again while the chips remain attached in wafer form, until covers have been mounted to all of the chips of the wafer. Thereafter, in such alternative process, the wafer is diced into individually covered chips.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A covered chip, comprising:
a chip having a front surface, an optically active circuit area and bond pads disposed at said front surface; and
an at least partially optically translucent or transparent unitary cover mounted to said front surface of said chip, having at least one optical element integrated in said unitary cover, aligned with said optically active circuit area and vertically spaced from said optically active circuit area.

2. A covered chip as claimed in claim 1, wherein said optical element is operable to perform at least one of: (i) altering a direction of light radiated from said active circuit area when said active circuit area produces the light; and (ii) altering a direction of light impinging on said optical element in a direction toward said active circuit area.

3. The covered chip as claimed in claim 1, wherein said optical element has a bottom surface adjacent said front surface of said chip and a top surface opposite said bottom surface, wherein at least one of said top and bottom surfaces is non-planar.

4. The covered chip as claimed in claim 1, wherein said unitary cover consists essentially of one or more polymers.

5. The covered chip as claimed in claim 1, wherein said covered chip further comprises at least one conductive interconnect extending from at least one of said bond pads through said unitary cover to a top surface of said unitary cover.

6. The covered chip as claimed in claim 1, wherein said unitary cover further comprises at least one through hole aligned to at least one of said bond pads, said covered chip further comprising at least one conductive interconnect extending from said at least one bond pad at least partially through said at least one through hole.

7. The covered chip as claimed in claim 1, wherein said optical element is a first optical element, said covered chip further comprising a second optical element mounted in alignment with said first optical element.

8. The covered chip as claimed in claim 7, wherein said unitary cover includes one or more raised mounts disposed above said top surface of said first optical element, said second optical element being mounted to said mounts.

9. A covered chip as claimed in claim 1, wherein said optical element includes at least one element selected from the group consisting of a lens, a diffraction grating, a hologram, an at least partially reflective reflector, and a filter.

10. A covered chip as claimed in claim 1, wherein said unitary cover consists essentially of silicon and includes a bottom surface adjacent to said front surface of said chip, a top surface opposite said bottom surface and a thinned region having a second surface between said top and bottom surfaces, said thinned region overlying said optically active circuit area, wherein said optical element includes said thinned region.

11. A covered chip as claimed in claim 10, wherein said optical element includes a sidewall extending upwardly from said bottom surface to said second surface, said optical element including a reflector disposed on said sidewall.

12. A covered chip as claimed in claim 11, wherein said reflector includes a metal coating disposed on said sidewall.

13. A covered chip as claimed in claim 11, wherein said active circuit area includes an optical source.

14. A covered chip as claimed in claim 13, wherein said optical source is a laser.

15. A covered chip, comprising:
a chip having a front surface, an optically active circuit area at said front surface and bond pads disposed on said front surface; and
a unitary cover mounted to said front surface of said chip, said unitary cover consisting essentially of one or more polymers, and having an inner surface adjacent to said chip and an outer surface opposite said inner surface, and including one or more mounts disposed at positions above said outer surface, said mounts adapted for mounting an optical element.

16. The covered chip as claimed in claim 15, further comprising said optical element mounted to said mounts.

17. The covered chip as claimed in claim 15, wherein said unitary cover includes an opening aligned with said active circuit area.

18. The covered chip as claimed in claim 17, wherein said unitary cover is essentially opaque to wavelengths of interest with respect to said active circuit area.

19. The covered chip as claimed in claim 16, wherein said unitary cover is essentially optically transmissive at wavelengths of interest with respect to said active circuit area and covers said active circuit area.

20. The covered chip as claimed in claim 15, wherein said covered chip further comprises at least one conductive interconnect extending from at least one of said bond pads through said unitary cover to a top surface of said unitary cover.

21. The covered chip as claimed in claim 15, wherein said unitary cover further comprises at least one through hole aligned to at least one of said bond pads, said covered chip further comprising at least one conductive interconnect extending from said at least one bond pad at least partially through said at least one through hole.

22. The covered chip as claimed in claim 20, wherein said one or more mounts are one or more first mounts and said unitary cover includes one or more second mounts disposed above said one or more first mounts and a second optical element mounted to said one or more second mounts.

23. The covered chip as claimed in claim 20, wherein said unitary cover further includes one or more stops disposed at said bottom surface, said stops maintaining said active circuit area at at least a minimum spacing from said optical element.

24. A method of simultaneously forming a plurality of covered optically active chips, comprising:
providing an array of optically active chips, each chip having a front surface and an optically active circuit area at said front surface;
providing an array of unitary optically transmissive covers, each cover having at least one of (i) an integrated optical element and (ii) a mount adapted to hold an optical element;
aligning at least ones of the chips to ones of the covers; and
simultaneously joining the ones of the chips to the aligned ones of the covers to form said covered chips.

25. The method as claimed in claim 24, wherein the ones of the chips include a plurality of chips but less than all of said chips so that the plurality of chips is aligned with a plurality of the covers and the plurality of the chips are simultaneously joined to the plurality of the covers.

26. The method as claimed in claim 24, wherein all of the chips of the array of chips are simultaneously aligned to all of the covers of the array of covers and all of the chips of the array of chips are simultaneously joined to all of the covers of the array of covers.

27. The method as claimed in claim 26, wherein said covers consist essentially of one or more polymers.

28. The method as claimed in claim 27, wherein at least some of the chips of the array remain attached to others of the chips while the chips are aligned and joined to the covers, the method further comprising severing the joined chips from each other to provide individual covered chips.

29. The method as claimed in claim 28, wherein the array of covers is provided as a unitary piece including said covers and a plurality of stress-bearing members connecting said covers.

30. The method as claimed in claim 29, wherein said stress-bearing members include springs.

31. The method as claimed in claim 29, further comprising supporting said array of covers temporarily on a platen having a coefficient of thermal expansion (CTE) which matches a CTE of said chips, each said cover spaced horizontally from at least one other of said covers, wherein said cover spacing corresponds to a chip spacing between ones of said optically active circuit areas of said chips, such that said array of covers is aligned and joined to said array of chips at an elevated temperature, despite a difference in a CTE between said array of covers and said chips.

32. The method as claimed in claim 31, further comprising detaching said platen from said array of covers after said joining.

33. The method as claimed in 31, wherein said covers are attached to said platen by a temporary adhesive.

34. The method as claimed in claim 33, wherein said adhesive is degradable by ultraviolet light, and said platen is detached from said array of covers by irradiating said adhesive with ultraviolet light.
